(19) United States
(12) Patent Application Publication
(10) Pub. No.: US 2006/0128144 A1
(43) Pub. Date: Jun. 15, 2006

(54) Interconnects having a recessed capping layer and methods of fabricating the same

(76) Inventors: Hyun-Mog Park, Portland, OR (US); Kenneth C. Cadien, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/013,891

(22) Filed: Dec. 15, 2004

(51) Int. Cl. H01L 21/4763

(52) U.S. Cl. 438/643

(57) ABSTRACT

Apparatus and methods of fabricating an interconnect having a recessed capping layer. An embodiment of the present invention relates to the fabrication of an interconnect for a microelectronic device which includes a recessed capping layer, which substantially eliminates topography issues present in the known devices and provides improved encapsulation of the interconnect to prevent electromigration of the conductive material thereof.

### BACKGROUND OF THE INVENTION

1. Field of the Invention

An embodiment of the present invention relates to microelectronic device fabrication. In particular, an embodiment of the present invention relates to a method of fabricating an interconnect having a recessed capping layer resulting in improved topography and improved encapsulation of the interconnect.

2. State of the Art

The microelectronic device industry continues to see tremendous advances in technologies that permit increased integrated circuit density and complexity, and equally dramatic decreases in power consumption and package sizes. Present semiconductor technology now permits single-chip microprocessors with many millions of transistors, operating at speeds of tens (or even hundreds) of MIPS (millions of instructions per second), to be packaged in relatively small, air-cooled microelectronic device packages. These transistors are generally connected to one another or to devices external to the microelectronic device by conductive traces and vias (hereinafter collectively referred to “interconnects”) through which electronic signals are sent and/or received.

One process used to form contacts is known as a “damascene process”. In a typical damascene process, as shown in FIG. 12, a photoresist material 402 is patterned on a first dielectric material layer 404 and the first dielectric material layer 404 is etched through the photoresist material 402 patterning to form a hole or trench 406 extending to at least partially through the first dielectric material layer 404, as shown in FIG. 13. The photoresist material 402 is then removed (typically by an oxygen plasma) and a barrier layer 408 is deposited within the hole or trench 406 on sidewalls 410 and a bottom surface 412 thereof to prevent conductive material (particularly copper and copper-containing alloys), which will be subsequent be deposited into the hole or trench 406, from migrating into the first dielectric material layer 404, as shown in FIG. 14. The barrier layer 408 used for copper-containing conductive materials are usually nitrogen-containing materials, including, but not limited to tantalum nitride and titanium nitride. The barrier layer 408 also extends abutting a first surface 414 of the first dielectric material layer 404. The migration of the conductive material can adversely affect the quality of microelectronic device, such as leakage current and reliability between the interconnects, as will be understood to those skilled in the art.

As shown in FIG. 15, a seed material 416, e.g., one including copper, is deposited on the barrier layer 408. The hole or trench 406 is then filled, usually by an electroplating process, with the conductive material (e.g., such as copper and alloys thereof), as shown in FIG. 16, to form a conductive material layer 418. Like the barrier layer 408, excess conductive material may form proximate the first dielectric material layer first surface 414. The resulting structure is planarized, usually by a technique called chemical mechanical polish (CMP), which removes the conductive material layer 418 and barrier layer 408 that is not within the hole from the surface of the dielectric material, to form the interconnect 422, as shown in FIG. 17.

As shown in FIGS. 18 and 19, the interconnect 422 is then capped with a capping layer 424 including, but not limited to, cobalt and alloys thereof. The capping layer 424 may be formed by any method known in the art, including plating techniques. The capping layer 424 prevents the electromigration of the conductive material of the interconnect 422 into a subsequently deposited second dielectric material layer 426, shown in FIGS. 20 and 21. The second dielectric material layer 426 may be deposited by any technique known in the art including but not limited to chemical vapor deposition.

However, since the capping layer 424 abuts the interconnect 422, its “elevation” difference will be translated into the second dielectric material layer 426 resulting in a non-planar topography 428, as shown in FIGS. 20 and 21. Of course, significant topography changes on any dielectric material layer surface is very challenging in lithography due to its limitation of DOF (Depth of Focus), as will be understood by those skilled in the art.

Furthermore, current interconnect structures may not provide sufficient encapsulation of the conductive material. For example, referring to back to FIGS. 18 and 19, the confluence 430 of the capping layer 424 and the barrier layer 408 (shown within the dashed circle) can provide insufficient coverage to prevent the conductive material of the interconnect 422 from electromigrating from between the capping layer 424 and the barrier layer 408.

Therefore, it would be advantageous to develop a method to form a capping layer, which results in improved topology and improved encapsulation of an interconnect.

### BRIEF DESCRIPTION OF THE DRAWINGS

While the specification concludes with claims particularly pointing out and distinctly claiming that which is regarded as the present invention, the advantages of this invention can be more readily ascertained from the following description of the invention when read in conjunction with the accompanying drawings to which:

FIGS. 1-9 illustrate cross-sectional views of an embodiment of a method of fabricating an interconnect of a microelectronic device, according to the present invention;

FIG. 10 is an oblique view of a handheld device having a microelectronic device an interconnect structure of the present integrated therein, according to the present invention;

FIG. 11 is an oblique view of a computer system having a heat dissipation device of the present integrated therein, according to the present invention; and

FIGS. 12-21 illustrate cross-sectional views of a method of fabrication a microelectronic device, as known in the art.

### DETAILED DESCRIPTION OF THE ILLUSTRATED EMBODIMENT

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

An embodiment of the present invention relates to the fabrication of an interconnect for a microelectronic device which includes a recessed capping layer, which substantially eliminates topography issues present in the known devices and provides improved encapsulation of the interconnect to prevent electromigration of the conductive material thereof.

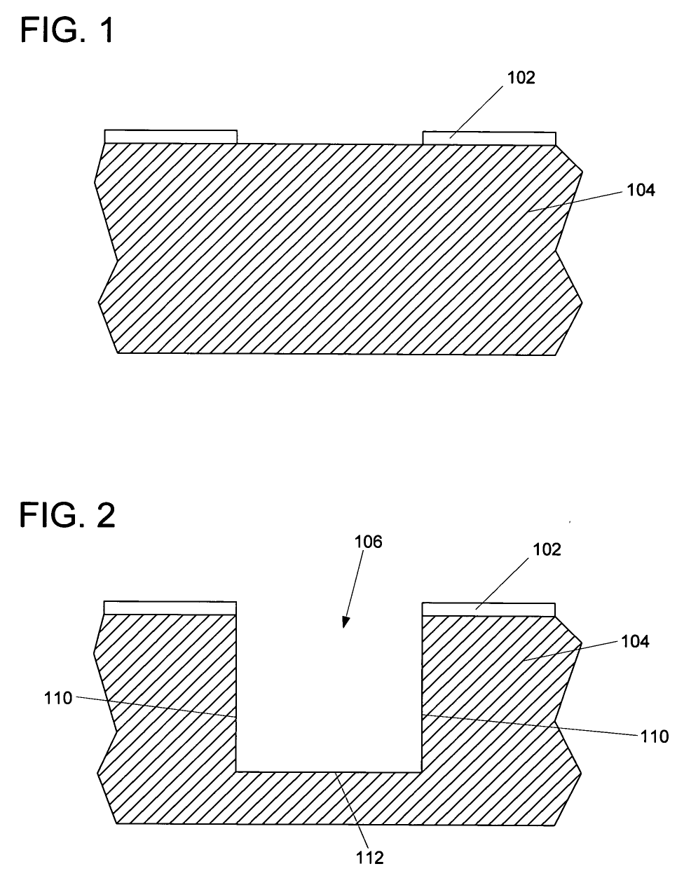

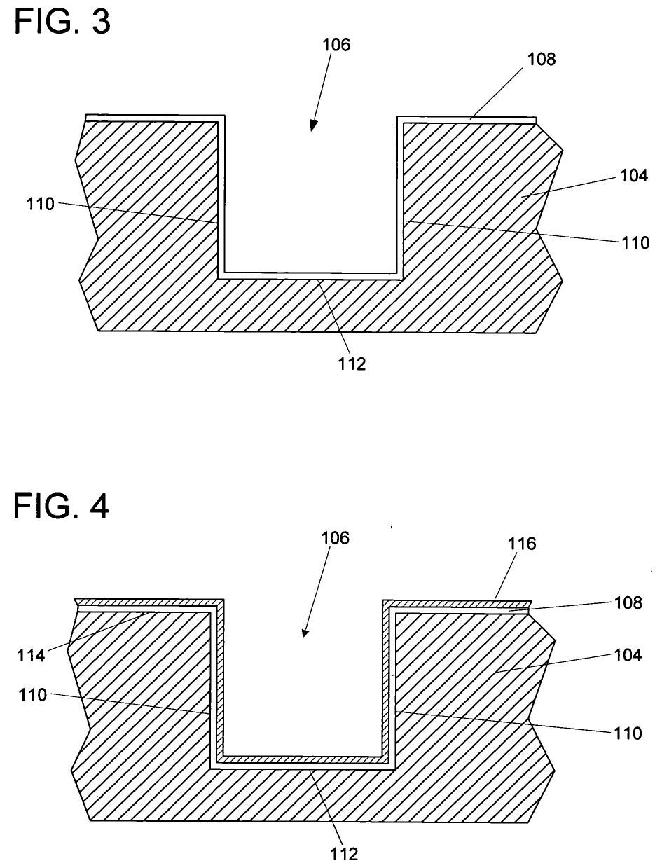

One embodiment of a process used to form an interconnect according to the present invention, comprises patterning a photoresist material 102 on a first dielectric material layer 104, as shown in FIG. 1. The first dielectric material layer 104 may include, but is not limited to, silicon dioxide, silicon nitride, carbon doped oxide, and the like. The first dielectric material layer 104 is etched through the photoresist material 102 patterning to form a hole or trench 106 (hereinafter collectively “opening 106”) extending to at least partially through the first dielectric material layer 104, as shown in FIG. 2. The photoresist material 102 is then removed (typically by an oxygen plasma) and a barrier layer 108 is deposited within the opening 106 on sidewalls 110 and a bottom surface 112 thereof to prevent conductive material (particularly copper and copper-containing alloys), which will be subsequent be deposited into the opening 106, from migrating into the first dielectric material layer 104, as shown in FIG. 3. The barrier layer 108 used for copper-containing conductive materials is usually a nitrogen-containing material, including, but not limited to tantalum nitride and titanium nitride. A portion of the barrier layer 108 also extends over and abutting a first surface 114 of the first dielectric material layer 104. It is, of course, understood that the opening 106 can be formed by any known technique including, but not limited to, ion milling and laser ablation.

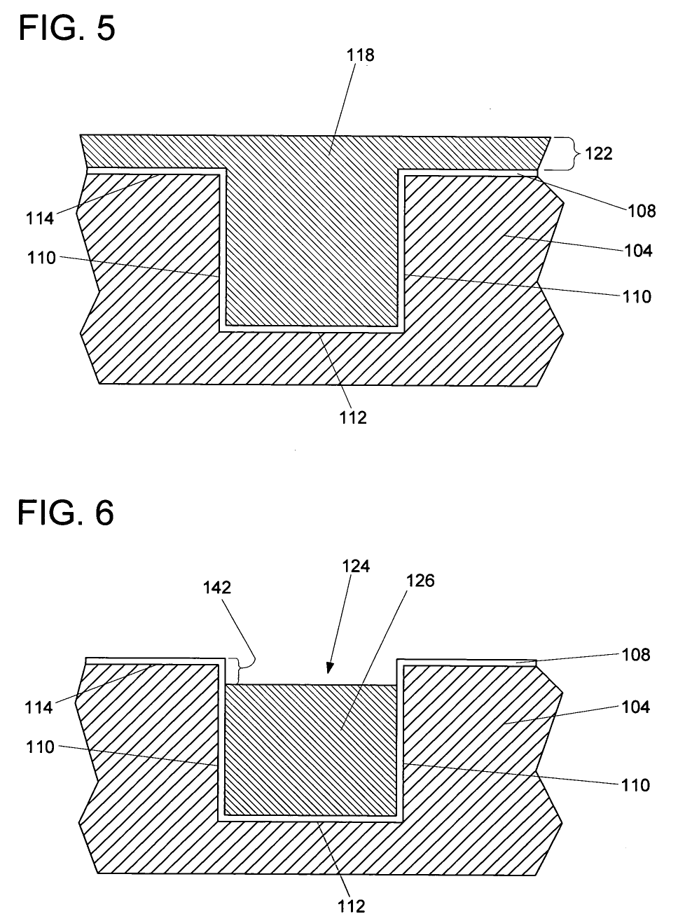

As shown in FIG. 4, a seed material 116 may be deposited on the barrier layer 108 by any method known in the art. The opening 106 is then filled with the conductive material, such as copper, aluminum, and alloys thereof, and the like, as shown in FIG. 5, to form a conductive material layer 118. The opening 106 may be filled by any known process, including but not limited to electroplating, deposition, and the like.

As previously discussed with regard to the barrier layer 108, excess conductive material 122 (e.g., any conductive material not within the opening 106) of the conductive material layer 118 may form proximate the dielectric material layer first surface 114. The resulting structure of FIG. 5 is then electropolished, as shown in FIG. 6. Electropolishing is a well-known process in which the topography of a conductive surface is smoothed by polarizing it anodically in certain electrolytes that are suitable for such application. In other words, electropolishing smooths rough metal surface. Electropolishing is finding its way into the microelectronic industry with the selective removal of metals during microelectronic device fabrication. A typical electropolishing system configuration may comprise a contact ring and a head which holds a microelectronic wafer facing downward in an electrolyte bath. An electrical basis is introduced to the metal of the microelectronic wafer through the contact ring, such that it becomes a cathode.

The electrolyte bath for copper-containing metallization generally comprises a phosphoric acid solution. When the copper-containing metallization is polarized anodically at low potentials, dissolution may occur at preferential crystallographic sites or planes having higher surface energy, such as the grain boundaries, resulting in etching of the copper-containing metallization.

Referring to FIG. 6, with an electropolishing process, the excess conductive material 122 is removed and the conductive material layer 118 within the hole or trench 102 is partially removed forming a recess 124 by controlling electropolish process time, thereby forming a recessed conductive material 126. This processing time is dependent on the concentration of the electrolyte in the bath and the electrical basis introduced, as will be understood by one skilled in the art.

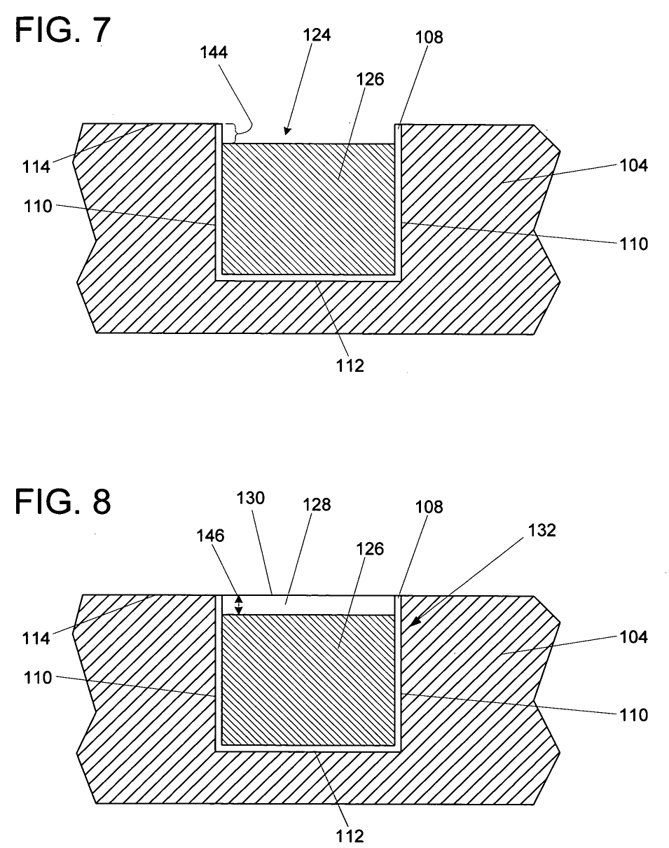

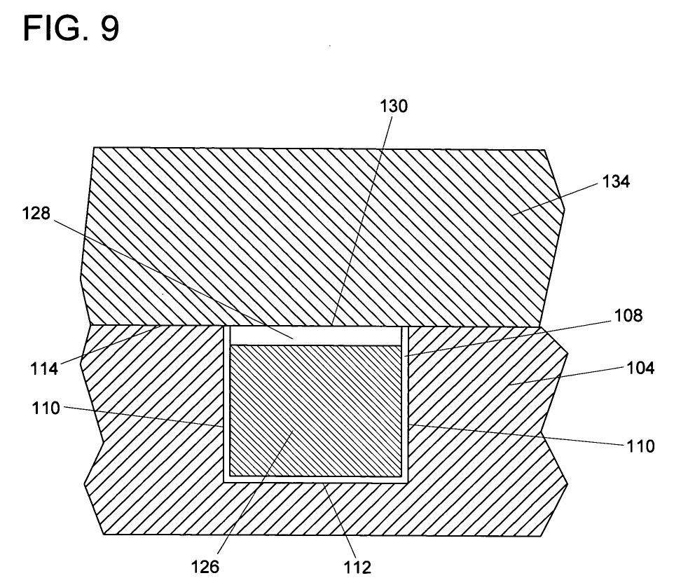

The portion of the barrier layer 108 extending over and abutting the first dielectric material layer first surface 114 is then removed, such as by a dry etch process, as shown in FIG. 7. As shown in FIG. 8, the recessed conductive material 126 is then capped with a recessed capping layer 128 including, but not limited to, cobalt and alloys thereof. Thus, an interconnect 132, comprising the barrier layer 108, the recessed conductive material 126, and the recessed capping layer 128, is formed. The recessed capping layer 128 may be formed by any method known in the art, including plating techniques. The recessed capping layer 128 is preferably formed to fill the recess 124 such that a first surface 130 of the recessed capping layer 128 is substantially planar to the first dielectric material layer first surface 114. As will be understood, by controlling the eletropolish duration, the capping layer thickness will match the recess 124 depth. The recessed capping layer 128 prevents the electromigration of the conductive material of the interconnect 132 into a subsequently deposited second dielectric material layer 134, shown in FIG. 9. The second dielectric material layer 134 may be deposited by any technique known in the art including but not limited to chemical vapor deposition.

Referring to FIGS. 1-8, in one embodiment, copper is employed as the conductive material layer 118 deposited over a tantalum/tantalum nitride barrier layer 108 into the opening 106 formed in a low-K dielectric material, such as carbon dope oxide. The copper conductive material layer 118 is electropolished with a stress free polishing system. The electropolishing can be conducted with an ACM Ultra SFP® System available from ACM Research Inc., Fremont, Calif., USA. The stress free polishing (electropolishing) on the ACM Ultra SFP® System can be achieved with a phosphoric acid/glyerine solution available from ACM Research Inc. under the product name EP-9000 at a temperature of between about 27 and 29 degree Celsius. The copper conductive material layer 118 is over-electropolished resulting in the recess 124, which in one example could be about 88 nm in depth 142 from the barrier layer to the recessed copper conductive material 126. The figures, of course, are not to scale.

In one embodiment, the incoming structure, such as a microelectronic device wafer, should be substantially flat. This can be achieved by either doing a pre-CMP step and leaving about 3500 angstroms of copper above the opening 106, or if the copper lines are dummified, the copper will be flat enough to electropolish without a pre-CMP step. Using a constant current (about 2 amps), a timed electropolish removes the copper overburden so that about 2000 angstroms remains. The over-polish to from the recess 124 is performed with a constant voltage timed process at a voltage of about 40 volts.

The portion of the tantalum/tantalum nitride barrier layer 108 extending over and abutting the first dielectric material layer first surface 114 is then removed, such as by a fluorine dry etch. The fluorine dry etch by achieved with a fluorine-containing gas, including but not limited to, CF₄, SF₆, NF₃, C₂F₆, and the like, with an inert carrier gas, such as argon, and a low ion energy bombardment. As will be understood to those skilled in the art, a fluorine dry etch can also etch copper, but the boiling point of the copper etch by-product is significantly higher than that of tantalum. Thus, the main copper etching mechanism is “sputtering” due to highly energetic ion bombardment. Therefore, so long as the ion bombardment energy is low enough, the tantalum/tantalum nitride barrier layer 108 can be selectively removed without etching the recessed copper conductive material 126. The operating parameters for the fluorine dry etch can be a pressure between about 40 and 60 mTorr, a power of between about 400 and 800 Watts (or even a broader range depending on the desired results), a fluorine-containing gas flow rate, specifically SF₆, between about 50 and 70 sccm, and a carrier gas flow rate, specifically argon, between about 140 and 160 sccm. With the removal of the tantalum/tantalum nitride barrier layer 108, the recess 124 in one example could have a depth 144 from the first dielectric material layer first surface 114 to the recessed copper conductive material 126 of about 10 nm. The figures, of course, are not to scale.

The recessed copper conductive material 126 can then be capped with a cobalt capping layer 134 by treating the recessed copper conductive material 126 to be hydrophobic, such as by silane based product or plasma assisted pre-treatment, which may also make the dielectric material 104 hydrophilic. The recessed copper conductive material 126 may be pre-cleaned to reduce any defects and redistributed copper. The pre-clean can be achieved using only wet chemistry or in combination with a polyvinyl acetate brush scrub system or a mega/ultra sonic cleaning to remove attached surface particles and plating related residues. Optionally, the recessed copper conductive material 126 may be palladium activated and subsequently post-activation clean, if the cobalt deposition is not self-initiating and requires a catalytic surface. The cobalt is deposited by electroless plating to fill the recess 124 (about 10 nm) to form the recessed capping layer 128. The cobalt may, of course, also be any binary, ternary, or quarternary cobalt alloy containing tungsten, phosphorus, boron, molybdenum, rhenium, or the like. The recessed cobalt capping layer 128 may be treated with a hydrofluoric acid/organic chemistry based cleaning step to remove redistributed copper and cobalt particles, as well as remove any damage from the first dielectric material first surface 114.

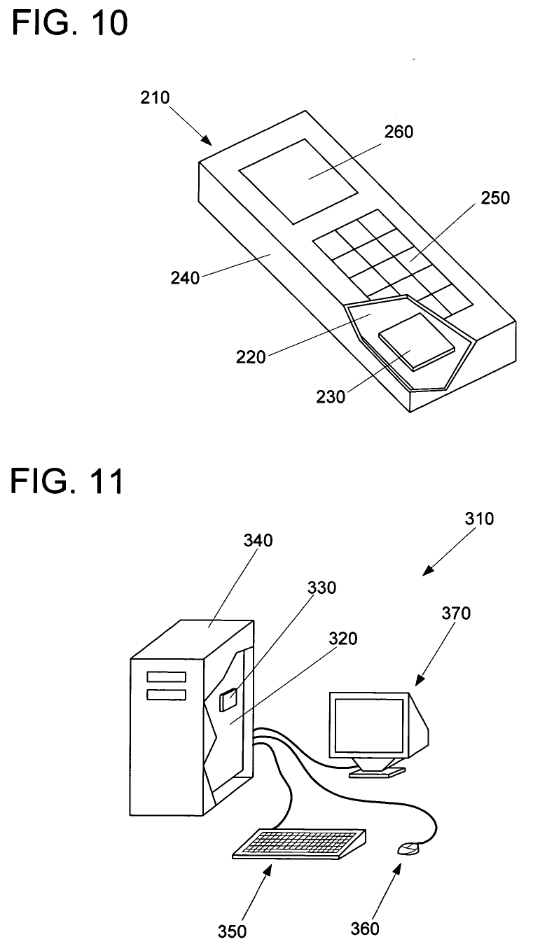

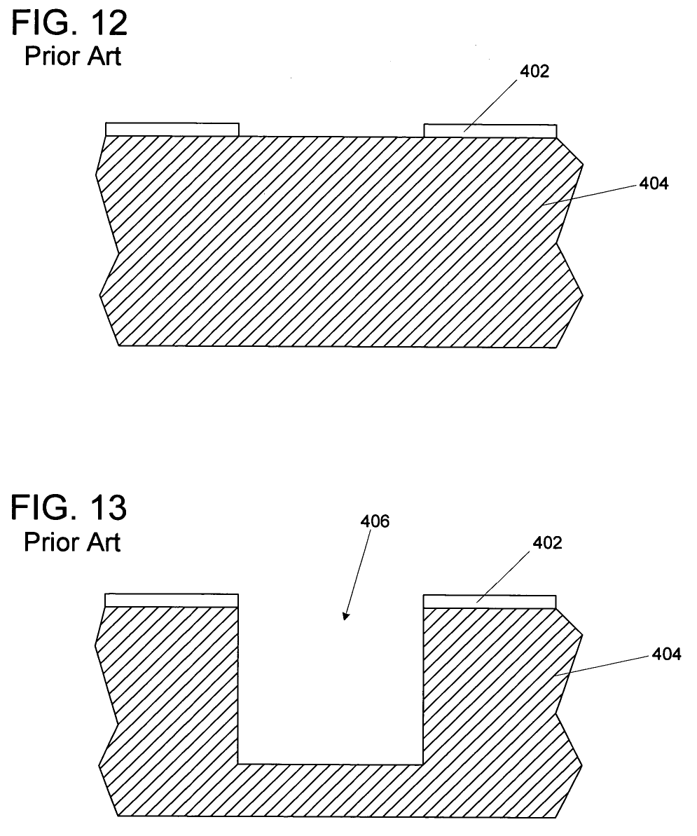

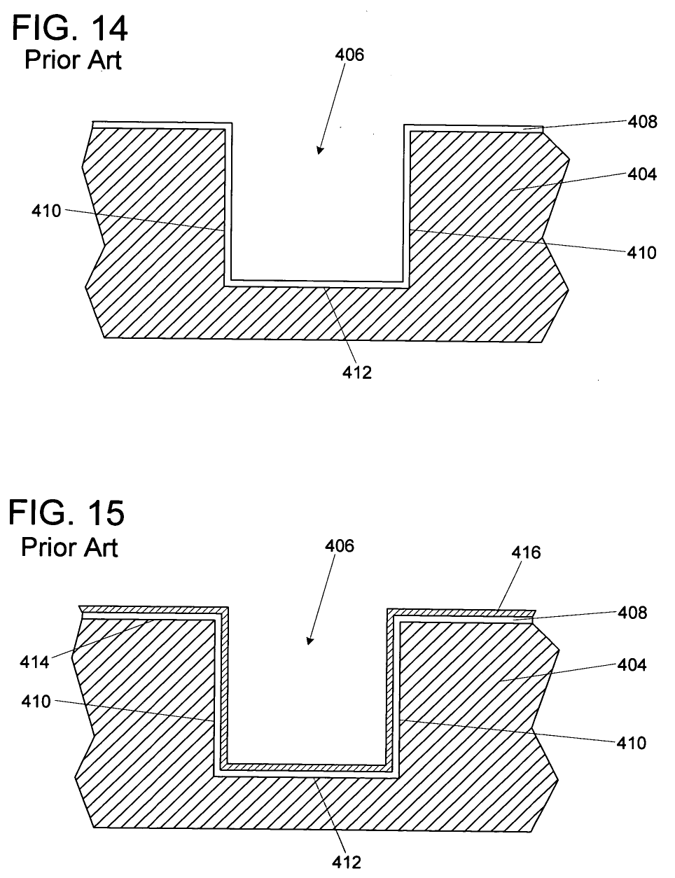

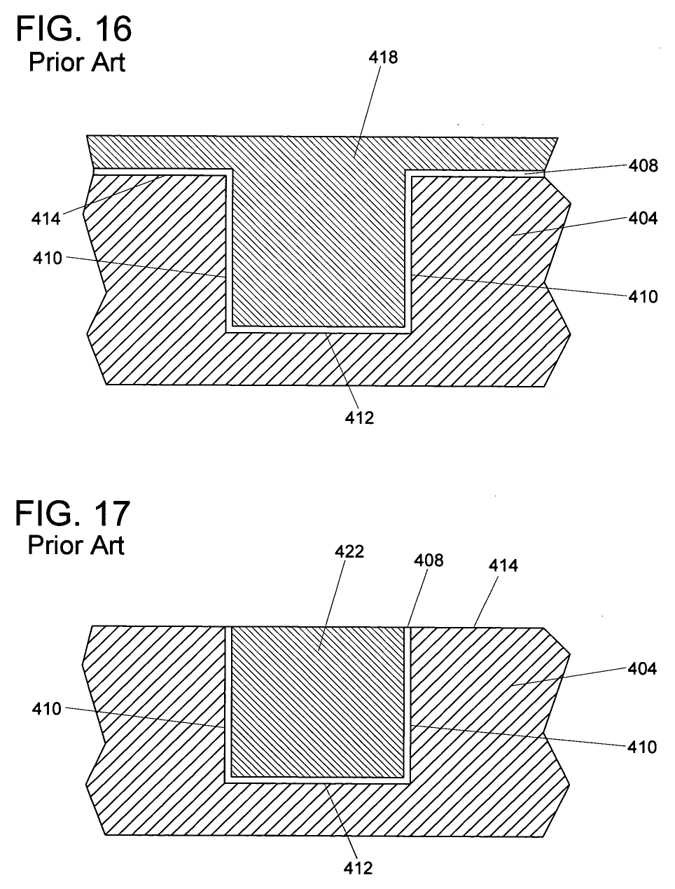

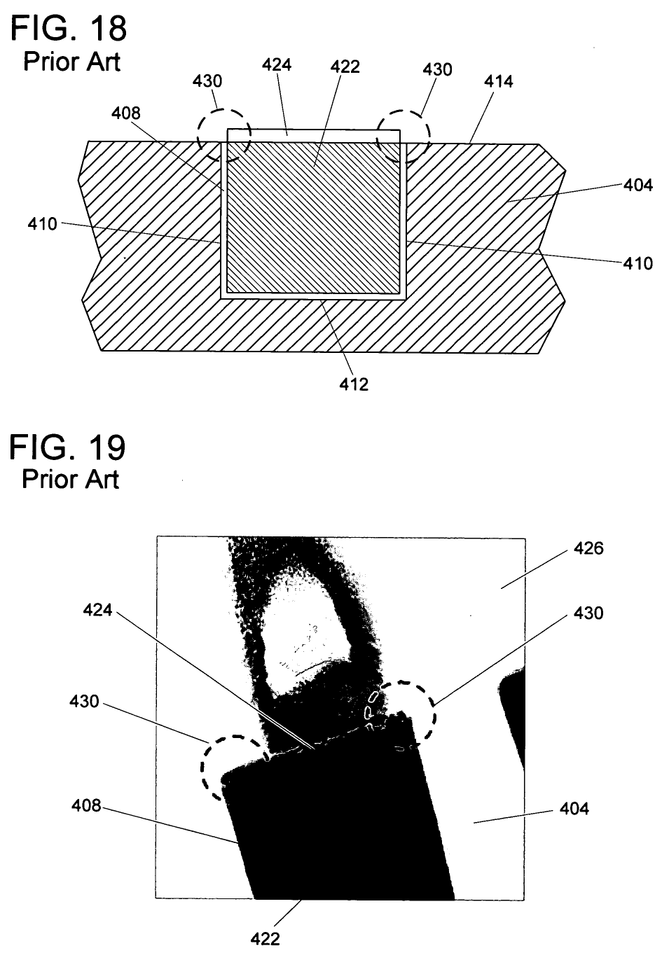

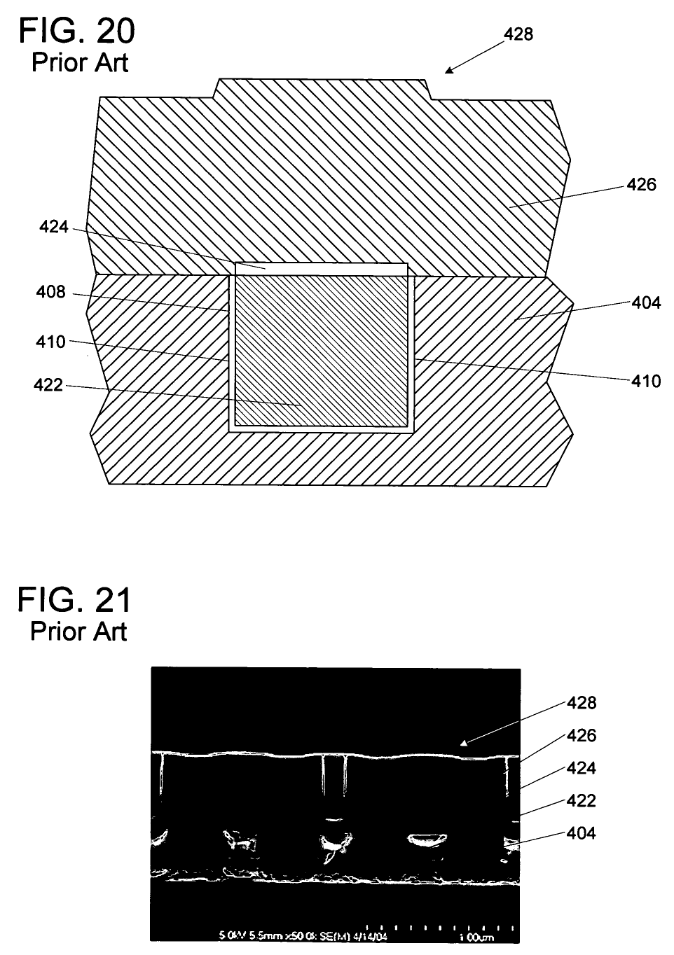

The packages formed with the interconnects having recessed capping layer of the present invention may be used in a hand-held device 210, such as a cell phone or a personal data assistant (PDA), as shown in FIG. 10. The hand-held device 210 may comprise an external substrate 220 with at least one microelectronic device assembly 230, including but not limited to, a central processing units (CPUs), chipsets, memory devices, ASICs, and the like, having at least one recessed capping layer as described above, within a housing 240. The external substrate 220 may be attached to various peripheral devices including an input device, such as keypad 250, and a display device, such an LCD display 260.

The microelectronic device assemblies formed with the adhesion layer of the present invention may also be used in a computer system 310, as shown in FIG. 11. The computer system 310 may comprise an external substrate or motherboard 320 with at least one microelectronic device assembly 330, including but not limited to, a central processing units (CPUs), chipsets, memory devices, ASICs, and the like, having at least one interconnect described above, within a housing or chassis 340. The external substrate or motherboard 320 may be attached to various peripheral devices including inputs devices, such as a keyboard 350 and/or a mouse 360, and a display device, such as a CRT monitor 370.

Having thus described in detail embodiments of the present invention, it is understood that the invention defined by the appended claims is not to be limited by particular details set forth in the above description, as many apparent variations thereof are possible without departing from the spirit or scope thereof.

1. An interconnect comprising:
a conductive material disposed within a dielectric material; and
a capping layer within said dielectric material abutting said conductive material, wherein a first surface of said capping layer is substantially planar to a first surface of a first layer of said dielectric material.

2. The interconnect of claim 1, further including a barrier layer disposed between said conductive material and said dielectric material.

3. The interconnect of claim 1, wherein the conductive material comprises copper.

4. A method of fabricating an interconnect, comprising:
providing at least one dielectric layer having a first surface;
forming at least one opening extending at least partially into said at least one dielectric layer from said dielectric layer first surface;
disposing a conductive material within said opening; and
disposing a capping layer within said opening to abut said conductive material, wherein a first surface of said capping layer is substantially planar with said dielectric layer first surface.

5. The method of claim 4, further comprising forming a barrier layer in said at least one opening prior to disposing said conductive material within said opening.

6. The method of claim 5, wherein forming said barrier layer comprises forming a tantalum nitride barrier layer.

7. The method of claim 4, wherein disposing said conductive material comprises:
depositing a layer of conductive material in said opening and proximate said dielectric material first surface; and
electropolishing said layer of conductive material layer to remove said conductive material from said dielectric layer first surface and to remove a portion of the conductive material within said opening to form a recess.

8. The method of claim 6, wherein depositing said conductive material layer comprises depositing a copper material layer.

9. The method of claim 6, wherein disposing said capping layer within said opening to abut said conductive material comprises plating capping layer on said conductive material layer to fill said recess.

10. A method of fabricating an interconnect, comprising:
providing at least one dielectric layer having a first surface;
forming at least one opening extending at least partially into said at least one dielectric layer from said dielectric layer first surface;
forming a barrier layer in said opening and abutting said dielectric layer first surface;
depositing a layer of conductive material in said opening and proximate said dielectric material first surface abutting said barrier layer; and
electropolishing said layer of conductive material layer to remove said conductive material from said barrier layer proximate said dielectric layer first surface and to remove a portion of the conductive material within said opening to form a recess;
removing a portion of said barrier layer proximate said dielectric material first surface; and
plating a capping layer within said opening to abut said conductive material layer to fill said recess, wherein a first surface of said capping layer is substantially planar with said dielectric layer first surface.

11. The method of claim 10, wherein forming said barrier layer comprises forming a tantalum nitride barrier layer.

12. The method of claim 10, wherein removing a portion of said barrier layer proximate said dielectric material first surface comprises etching said barrier layer portion with a fluorine dry etch.

13. The method of claim 10, wherein depositing said conductive material layer comprises depositing a copper material layer.

14. The method of claim 10, electropolishing said layer of conductive material layer to remove said conductive material from said barrier layer proximate said dielectric layer first surface and to remove a portion of the conductive material within said opening to form a recess comprises electropolishing said conductive material layer with a phosphoric acid solution.

15. The method of claim 10, wherein plating said capping layer within said opening comprising plating a cobalt containing material within said opening.

16. The method of claim 15, wherein plating said cobalt containing material within said opening comprises plating a binary, ternary, or quarternary cobalt alloy.

17. The method of claim 16, wherein plating said cobalt alloy comprises plating a cobalt alloy containing at least one additional metal selected from the group consisting of tungsten, phosphorus, boron, molybdenum, or rhenium.

18. An electronic system, comprising:
an external substrate within a housing; and
at least one microelectronic device package attached to said external substrate, having at least one interconnect including:
a conductive material disposed within a dielectric material; and
a capping layer abutting said conductive material, wherein a first surface of said capping layer is substantially planar to a first surface of a first layer of said dielectric material; and
an input device interfaced with said external substrate; and
a display device interfaced with said external substrate.

19. The system of claim 18, wherein said interconnect further includes a barrier layer disposed between said conductive material and said dielectric material.

20. The system of claim 18, wherein the conductive material of said interconnect comprises copper.
